(19) United States
(12) Patent Application Publication
(10) Pub. No.: US 2024/0050977 A1
(43) Pub. Date: Feb. 15, 2024

(54) COATING TREATMENT APPARATUS, COATING TREATMENT METHOD, AND COMPUTER STORAGE MEDIUM

(71) Applicant: Tokyo Electron Limited, Tokyo (JP)

(72) Inventor: Shogo INABA, Koshi City, Kumamoto (JP)

(21) Appl. No.: 18/260,575

(22) PCT Filed: Jan. 4, 2022
(86) PCT No.: PCT/JP2022/000015

§ 371 Date: Jul. 6, 2023

(30) Foreign Application Priority Data
Jan. 12, 2021 (JP) 2021-003100

(51) Int. Cl. B05C 11/10; B05C 11/08

(52) U.S. Cl. CPC B05C 11/10; B05C 11/08; H01L 21/6838

(57) ABSTRACT

A coating treatment apparatus for applying a coating solution to a peripheral portion of a substrate, includes: a holding and rotating part holding and rotating the substrate; a coating solution supply nozzle supplying the coating solution to the peripheral portion of the substrate; a moving mechanism moving the coating solution supply nozzle; and a controller controlling the holding and rotating part, coating solution supply nozzle, and moving mechanism, wherein the controller performs control of, while rotating the holding and rotating part: by controlling the moving mechanism while supplying the coating solution by the coating solution supply nozzle, both moving the coating solution supply nozzle from an outside of a perimeter of the substrate to a predetermined position at a periphery on the substrate at a first speed and then moving the coating solution supply nozzle from the predetermined position to the outside of the perimeter at a higher second speed.

### TECHNICAL FIELD

This disclosure relates to a coating treatment apparatus, a coating treatment method, and a computer storage medium.

### BACKGROUND ART

A treatment of applying a coating solution to a peripheral portion of a substrate such as a semiconductor wafer (hereinafter, sometimes simply called a wafer) is conventionally performed.

In this regard, Patent Document 1 discloses a peripheral portion coating apparatus including a rotating and holding part for horizontally holding and rotating a circular substrate, a nozzle for supplying a coating solution in order to form a coating film at a peripheral portion of a front surface of the substrate, a moving mechanism for moving the nozzle in order to move a supply position of the coating solution between the peripheral portion of the substrate and the outside position of the substrate, and a controller for outputting a control signal for controlling the rotation of the substrate by the rotating and holding part, the discharge of the coating solution from the nozzle, and the movement of the nozzle by the moving mechanism. The controller outputs the control signal so as to move the supply position of the coating solution from the outside of the substrate toward the peripheral portion of the substrate while rotating the substrate and supplying the coating solution from the nozzle, apply the coating solution in a wedge shape having an angle of 10° or less when viewing the substrate in plane, then stop the movement of the nozzle while continuing the rotation of the substrate and the supply of the coating solution, apply the coating solution in a band-shape along the peripheral portion of the substrate, and bring an end portion of the coating solution applied in the band-shape into contact with the coating solution applied in the wedge-shape to thereby apply the coating solution over the whole circumference of the substrate.

### PRIOR ART DOCUMENT

### Patent Document

Patent Document 1: Japanese Laid-open Patent Publication No. 2013-62436

### DISCLOSURE OF THE INVENTION

### Problems to be Solved by the Invention

The technique according to this disclosure accurately forms a coating film on a side surface of a peripheral portion of a substrate.

### Means for Solving the Problems

An aspect of this disclosure is a coating treatment apparatus for applying a coating solution to a peripheral portion of a substrate, the coating treatment apparatus including: a holding and rotating part configured to hold and rotate the substrate; a coating solution supply nozzle configured to supply the coating solution to the peripheral portion of the substrate held by the holding and rotating part; a moving mechanism configured to move the coating solution supply nozzle; and a controller configured to control the holding and rotating part, the coating solution supply nozzle, and the moving mechanism, wherein the controller is configured to perform control of, while rotating the holding and rotating part which holds the substrate: moving the coating solution supply nozzle from an outside of a perimeter of the substrate to a predetermined position at a periphery on the substrate at a first speed by controlling the moving mechanism while supplying the coating solution by the coating solution supply nozzle; and then moving the coating solution supply nozzle from the predetermined position to the outside of the perimeter of the substrate at a second speed higher than the first speed by controlling the moving mechanism while supplying the coating solution by the coating solution supply nozzle.

### Effect of the Invention

According to this disclosure, it is possible to accurately form a coating film on a side surface of a peripheral portion of a substrate.

### BRIEF DESCRIPTION OF THE DRAWINGS

FIG. 1 is an explanatory view illustrating a formation state of a protective film at a peripheral portion of a wafer.

FIG. 2 is an explanatory view illustrating a state where a protective liquid adheres to an inner surface edge of a cup.

FIG. 3 is an explanatory view of a side cross section schematically illustrating the outline of a configuration of a coating treatment apparatus according to an embodiment.

FIG. 4 is an explanatory view of a plane schematically illustrating the outline of the configuration of the coating treatment apparatus according to the embodiment.

FIG. 5 is an explanatory view illustrating the movement of a nozzle by a coating treatment method according to the embodiment.

FIG. 6 is an explanatory view illustrating an appearance of splashing of a resist solution at a scan-out time of a nozzle from the wafer.

FIG. 7 is an explanatory view illustrating a state where a protective film is formed down to a lower side of a peripheral portion of the wafer.

FIG. 8 is an explanatory view illustrating a state where a protective film is formed only at an upper side of the peripheral portion of the wafer.

### EMBODIMENTS FOR CARRYING OUT THE INVENTION

In a manufacturing process of a semiconductor device or the like, a series of photolithography processes including a resist coating treatment of supplying a resist solution onto the wafer to form a resist film are performed to form a predetermined resist pattern on the wafer. The series of processes are performed in a coating and developing treatment system including various kinds of solution treatment apparatuses for treating the wafer, a heat treatment apparatus, a transfer apparatus for transferring the wafer, and so on. Further, on the wafer for which the photolithography processes have been finished, an etching treatment and so on are performed thereafter, and then the series of treatments of the photolithography processes are performed again in some cases.

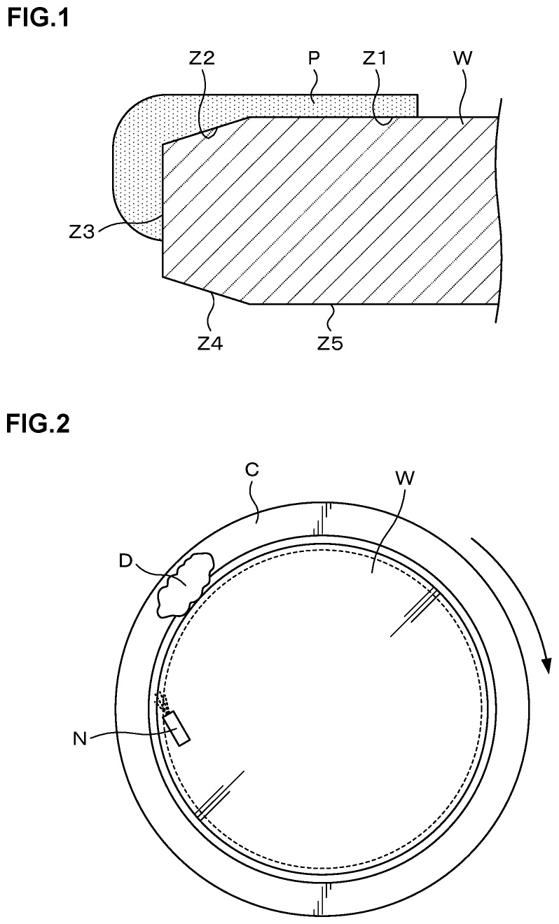

In the processes, for the purpose of protecting a peripheral portion of the wafer at the etching treatment time, a coating treatment of forming a protective film at the peripheral portion is sometimes performed. Explaining this in more detail based on FIG. 1, the peripheral portion of a wafer W is roughly divided as illustrated into a zone Z1 that is an upper surface side flat portion, a zone 2 that is a slope continuing from the zone Z1, a zone Z3 that is a vertical side end surface (peripheral portion side end surface) continuing from the zone Z2, a zone Z4 that is a slope continuing from the zone Z3, and a zone Z5 that is a lower surface side flat portion continuing from the zone Z4.

Further, a protective film P is formed on the zone Z1, the zone Z2, and the zone Z3 on which the resist pattern is not formed at the etching treatment time and which are thus susceptible to damage by an etchant. As the protective film P, for example, a resist film with a resist solution is used.

The coating treatment for the peripheral portion is conventionally performed by the peripheral portion coating treatment apparatus. More specifically, while the rotating and holding part such as a spin chuck holding the wafer is rotating the wafer, a protective liquid supply nozzle N for forming a protective film illustrated in FIG. 2 is moved from an outside of a perimeter of the wafer W to a center side of the wafer W while discharging the protective liquid and stopped at an end portion on the center side of the wafer W in a coating region, and then the protective liquid supply nozzle N is retracted again to the outside of the perimeter of the wafer W. This forms the protective film P on the zone Z1, the zone Z2, and the zone Z3 at the peripheral portion of the wafer W as illustrated in FIG. 1.

Then, for forming the protective film P in a desired region, for example, a 60% to 80% region from the upper end in the zone Z3, the rotation speed of the rotating and holding part such as a spin chuck is adjusted.

Incidentally, a cup C illustrated in FIG. 2 is arranged on the outside of the rotating and holding part such as a spin chuck, and it has been found that if the rotating and holding part is rotated at a high speed at the time when forming the protective film in the desired region of the zone Z3 as explained above, the protective liquid splashes to an edge of the cup C, particularly, an inner surface of a later-explained block body provided at edge of the cup C and dirt D due to the protective liquid adheres to the edge inner surface of the cup C.

Hence, the technique according to this disclosure accurately forms a protective film on a side surface of a peripheral portion while suppressing the adhesion of a protective liquid to an inner surface edge of a cup when applying a coating solution to the peripheral portion of a substrate such as a wafer.

Hereinafter, an embodiment will be explained with reference to the drawings. Note that the same codes are given to components having substantially the same functional configurations herein to omit redundant explanation.

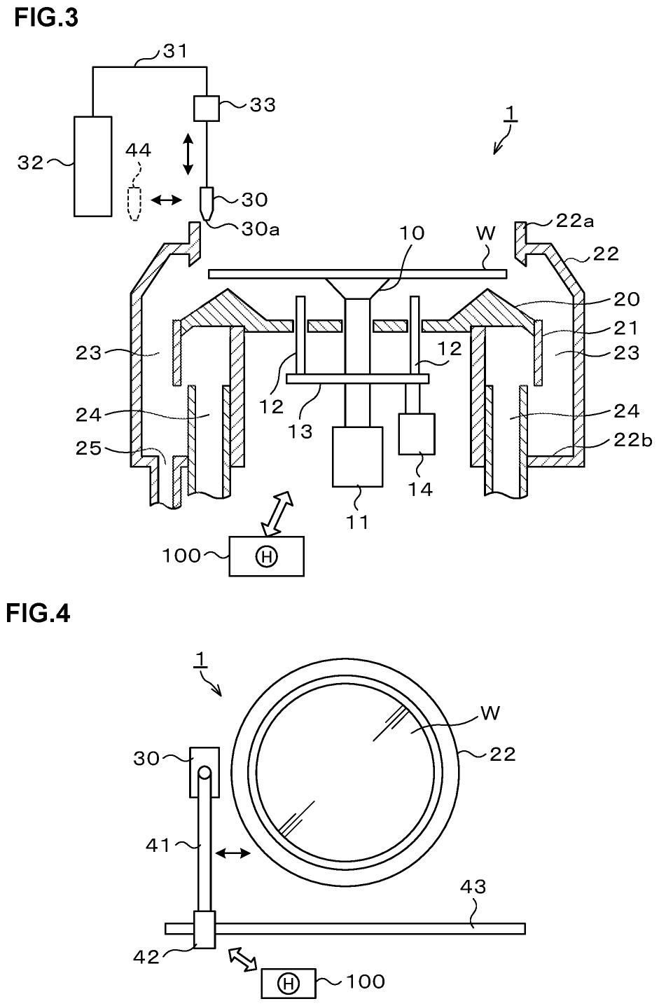

FIG. 3 schematically illustrates a longitudinal side of a coating treatment apparatus 1 according to an embodiment, and FIG. 4 is a view schematically illustrating a plane of the same. The coating treatment apparatus 1 is configured as an apparatus which applies, for example, a resist solution as a protective liquid to a peripheral portion of the wafer W to form a protective film. The coating treatment apparatus 1 includes a spin chuck 10 as a holding and rotating part. The spin chuck 10 is configured to horizontally hold the wafer W being a circular substrate having a diameter of, for example, 300 mm by vacuum suction. The spin chuck 10 is connected to a rotation drive 11 including a motor or the like. The rotation drive 11 rotates the spin chuck 10 around the vertical at a rotation speed according to a control signal output from a later-explained controller 100.

The delivery of the wafer W to/from the spin chuck 10 is performed by raising and lowering of three support pins 12 (only two support pins being illustrated in the drawing for convenience of illustration) for supporting a rear surface of the wafer W. The support pins 12 are provided on a base 13, and the base 13 freely rises and lowers by drive of a raising and lowering mechanism 14.

A guide ring 20 having a cross section in a mountain shape is provided on the lower side of the spin chuck 10, and an annular outer peripheral wall 21 extending downward is provided at an outer peripheral portion of the guide ring 20. Further, a cup 22 is arranged in a manner to surround the spin chuck 10 and the guide ring 20. More specifically, the cup 22 has an upper surface open in a circular shape and has a form surrounding the wafer W held on the spin chuck 10. Further, a cylindrical block body 22a is provided at an inner rim of a top portion of the cup 22. The block body 22a has a function of suppressing release of mist in the cup 22 to the outside and appropriately guiding a downflow into the cup 22.

As explained above, the cup 22 is open at the upper side so that the wafer W can be delivered to the spin chuck 10. Between an inner side peripheral surface of the cup 22 and the outer peripheral wall 21 of the guide ring 20, a gap 23 constituting a discharge passage is formed. At a bottom part 22b of the cup 22, an exhaust pipe 24 standing upward from the bottom part 22b is provided. Further, a drain port 25 is provided at the bottom part 22b of the cup 22.

The coating treatment apparatus 1 includes a nozzle 30 as a coating solution supply nozzle which supplies a protective liquid (coating solution). The nozzle 30 is formed with a discharge port 30a at a lower end surface. The nozzle 30 is connected via a resist solution supply pipe 31 to a resist solution supply source 32 which stores a resist solution. The resist solution supply source 32 includes a pump and pressure-feeds the resist solution to the nozzle 30 side, and the pressure-fed resist solution is discharged from the discharge port 30a. The resist solution supply pipe 31 is provided with a supply equipment group 33 including a valve, a flow rate regulating vale, and so on, so that the supply, stop, and supply amount to the nozzle 30 of the resist solution are controlled based on a control signal output from the controller 100.

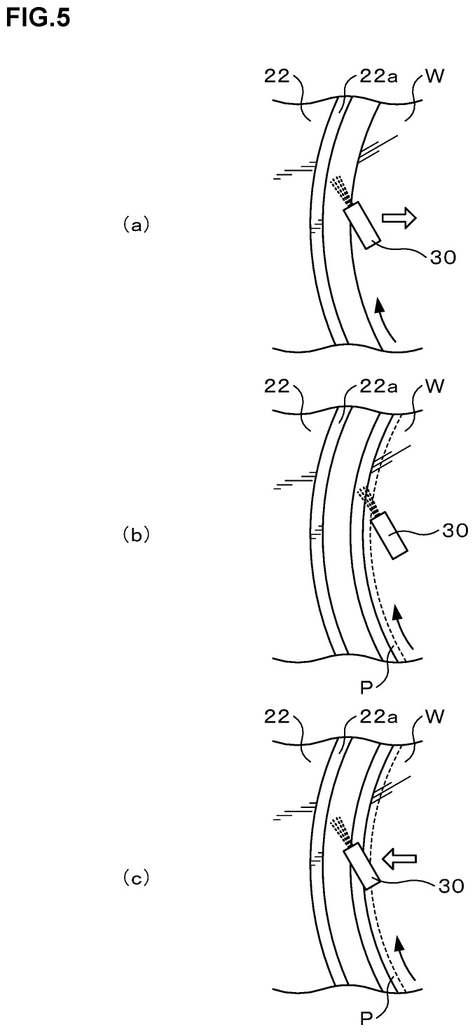

The nozzle 30 is supported by an arm 41 extending in the horizontal direction as illustrated in FIG. 4. Note that the nozzle 30 is supported in the vertical direction in FIG. 3 for convenience of illustration, but is actually arranged obliquely at a predetermined angle, for example, about 30 degrees with respect to a tangent of the wafer W in plan view and is directed to the outside of the wafer W as illustrated in later-explained FIG. 5. Further, the nozzle 30 is arranged not vertical but inclined at a predetermined angle, for example, about 30 degrees to the horizontal plane of the wafer W. These arrangement angles of the nozzle 30 are decided in arbitrary ranges.

The arm 30 is connected to a moving mechanism 42 via an arm 41. The moving mechanism 42 can move along a guide rail 43 extending in the lateral direction and raise and lower the arm 41. Further, the moving mechanism 42 moves according to the control signal from the controller 100, and the movement of the moving mechanism 42 enables the nozzle 30 to move between a standby position 44 provided outside the cup 22 and the periphery of the wafer W. Further, the moving distance, moving speed, and moving direction of the moving mechanism 42 are also controlled by the control signal from the controller 100.

The coating treatment apparatus 1 having the above configuration is controlled by the controller 100 as has been explained. The controller 100 is composed of a computer including, for example, a CPU, a memory, and so on, and has a program storage (not illustrated). The program storage stores a program for controlling various treatments in the coating treatment apparatus 1. Note that the above program may be the one recorded in a computer-readable storage medium H and installed from the storage medium into the controller 100. The storage medium H may be a transitory one or a non-transitory one.

Next, one example of a coating treatment method using the coating and developing system 1 having the above configuration will be explained. First, when the wafer W is suction-held on the spin chuck 10, the rotation drive 11 rotates the wafer W. Then, the nozzle 30 is moved from the already-mentioned standby position 44 illustrated in FIG. 3 to a center side of the wafer W, and the discharge of the resist solution is started at the inside of the cup 22 and at the outside of the perimeter of the wafer W as illustrated in FIG. 5(a), more specifically, at a position between an inner peripheral surface of the block body 22a of the cup 22 and an outside end of the wafer W. In this state, the nozzle 30 is moved to a predetermined position at the peripheral portion of the wafer W at a first speed, for example, 1 to 10 mm/sec. (scan-in) The predetermined position here is a position where a desired width in a radial direction of the protective film to be formed with the resist solution can be realized. The width of the protective film is set according to the characteristics and property of the protective film to be formed and the kind of the etching treatment thereafter, and is, for example, about 1 to 5 mm.

Then, once the nozzle 30 reaches the predetermined position as illustrated in FIG. 5(b), the nozzle 30 is stopped. Then, the nozzle 30 continues discharging the resist solution as it is while the wafer \V is rotated, for example, 1 to 5 times. Thus, a protective film P with the resist solution is formed having the aforementioned width at the peripheral portion of the wafer W.

Then, as illustrated in FIG. 5(c), the nozzle 30 is moved from the predetermined position in FIG. 5(b) to the outside of the perimeter of the wafer W at a second speed higher than the aforementioned first speed, for example, a speed exceeding 50 mm/sec., preferably, a speed of 80 to 200 mm/sec. (scan-out). Thereafter, the discharge of the resist solution is stopped, and the nozzle 30 is then moved to the standby position 44.

By discharging the resist solution to the peripheral portion of the wafer W in the above manner, the protective film P is formed for the zone Z1, the zone Z2, and the zone Z3 of the peripheral portion of the wafer W as illustrated in FIG. 1. Further, it has been confirmed that the dirt D adhering to the edge inner surface of the cup C as illustrated in FIG. 2 which is conventionally recognized is not generated. More specifically, it has been confirmed that the dirt D is not generated on the inner peripheral surface of the block body 22a due to splashing of the protective liquid to the inner peripheral surface of the block body 22a.

The fact that the resist solution adheres to the block body 22a to cause the dirt D shows the possibility that the resist solution splashes to the outer surface of the cup 22 beyond the block body 22a. There also is a possibility that a resist solution PL splashed to the inner peripheral surface of the block body 22a collides with the inner peripheral surface and bounces back onto the wafer W and adheres to a region not applied with the resist solution. If the resist solution adheres and accumulates on the inner peripheral surface of the block body 22a, the risk of the bouncing back also increases. On the other hand, the inner surface of the cup 22 can be cleaned with a cleaning solution such as a solvent, but the cleaning of the block body 22a is difficult. Accordingly, suppression and prevention of splashing of the protective liquid to the inner peripheral surface of the block body 22a can solve these problems.

The inventors have researched in various experiments and found that the speed when the nozzle 30 moves to the predetermined position (at scan-in time) and the speed when the nozzle 30 moves from the predetermined position to the outside of the perimeter of the wafer W (at scan-out time) are conventionally the same. It further has been found that the protective liquid does not adhere to the edge inner surface of the cup 22 when the nozzle 30 moves to the predetermined position (at scan-in time) but the protective liquid adheres to the edge inner surface of the cup 22 when the nozzle 30 moves from the predetermined position to the outside of the perimeter of the wafer W (at scan-out time).

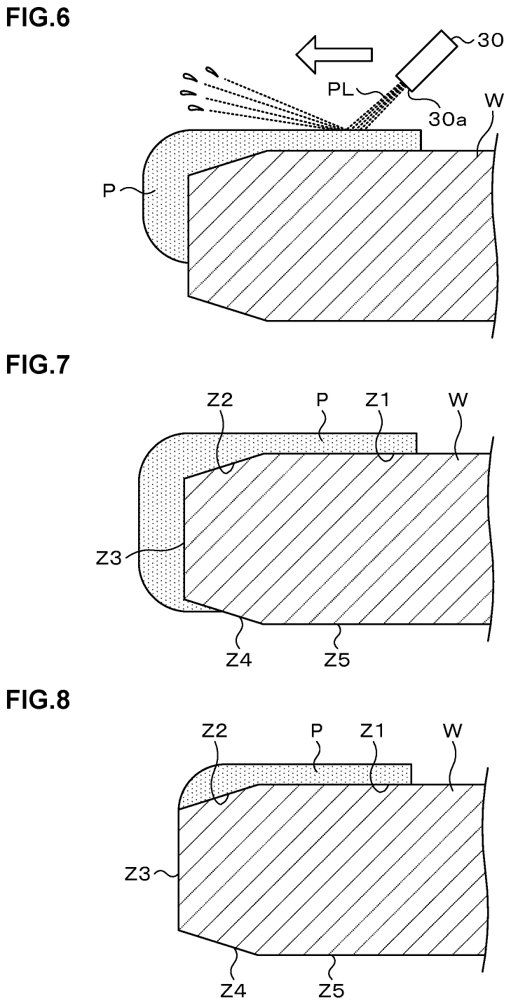

Further, the inventors have examined the cause of the protective liquid adhering to the edge inner surface of the cup C and the inner peripheral surface of the block body 22a, and found that the adhesion of the protective liquid to the edge inner surface of the cup C is caused when the protective film P has already been formed on the upper surface of the peripheral portion of the wafer W and the resist solution PL is further discharged thereon, the discharged resist solution PL collides with the protective film P which has not yet dried out and the resist solution PL vigorously splashes at that time as illustrated in FIG. 6. Therefore, if the time when the resist solution PL colliding and splashing as above is shortened as much as possible, the amount of the protective liquid splashing and adhering to the edge inner surface of the cup 22 and the inner peripheral surface of the block body 22a can be reduced accordingly.

Therefore, by making the speed at the scan-out time of the nozzle 30 higher than the speed at the scan-out time of the nozzle 30 as in the above embodiment, it becomes possible to shorten the time when the discharged resist solution PL collides with the protective film P which has not yet dried out and thereby suppress the adhesion of the splashed resist solution PL to the edge inner surface of the cup 22, in particular, the inner peripheral surface of the block body 22a.

Incidentally, the protective film P of this kind needs to be formed for the zone Z1, the zone Z2, and the zone Z3 of the peripheral portion of the wafer W as illustrated in FIG. 1, and a formation region in the zone Z3 preferably covers a 60 to 80% region from the upper end. Further, the control of the formation region is performed by the rotation speed of the wafer W when the nozzle 30 is discharging the resist solution being the protective liquid.

For example, if the rotation speed of the wafer W is too low, the protective film P goes around not only to the zone Z3 but alto to the zone Z4 as illustrated in FIG. 7, resulting in interference with subsequent transfer and treatments. On the other hand, if the rotation speed of the wafer W is too high, the protective film P does not reach the zone Z3 but possibly covers only the zones Z1, Z2 as illustrated in FIG. 8, resulting in failure of the protection of the zone Z3 at the etching time, the protection being the original purpose of the protective film P.

Therefore, the control of the rotation speed of the wafer W at the discharge of the protective liquid is important, but if controlled while focusing only on the rotation speed of the wafer W, the resist solution PL splashing at the scan-out time may possibly adhere to the edge inner surface of the cup 22 and the inner peripheral surface of the block body 22a as has been explained. Therefore, it is a very difficult problem how to suppress the adhesion of the protective solution PL to the inner surface edge of the cup 22, in particular, the inner peripheral surface of the block body 22a while arbitrarily performing the control of the rotation speed of the wafer W at the protective liquid discharge time.

In this regard, as has been explained above, the technique of this disclosure can suppress the adhesion of the protective liquid to the inner surface edge of the cup 22, in particular, the inner peripheral surface of the block body 22a by making the speed at the scan-out time of the nozzle 30 higher than the speed at the scan-in, thereby making it possible to arbitrarily control the rotation speed of the wafer W while focusing only on the control of the formation region of the protective film P in the zone Z3. Therefore, the technique according to this disclosure can accurately form the coating film on the side surface of the peripheral portion of the substrate, and suppress the adhesion of the resist solution PL to the inner surface edge of the cup, in particular, the inner peripheral surface of the block body 22a.

According to the findings of the inventors, by keeping the rotation speed of the wafer W at 500 rpm or more, preferably, 800 rpm to 2000 rpm together with the moving speed at the scan-out time of the nozzle 30, it becomes possible to fall the formation region of the protective film P in the zone Z3 of the peripheral portion of the wafer W to the 60 to 80% range, and to suitably suppress the adhesion of the resist solution PL being the protective liquid to the inner surface edge of the cup 22.

The embodiment disclosed herein is an example in all respects and should not be considered to be restrictive. Various omissions, substitutions and changes may be made in the embodiment without departing from the scope and spirit of the attached claims.

### EXPLANATION OF CODES

1 coating treatment apparatus
10 spin chuck
11 rotation drive
12 support pin
13 base
14 raising and lowering mechanism
20 guide ring
21 outer peripheral wall
22 cup
22a block body
23 gap
24 exhaust pipe
25 drain port
30 nozzle
30a discharge port
31 resist solution supply pipe
32 resist solution supply source
33 supply equipment group
41 arm
42 moving mechanism
43 guide rail
100 controller
H storage medium
P protective film
PL resist solution
W wafer
Z1 to Z5 zone

1. A coating treatment apparatus for applying a coating solution to a peripheral portion of a substrate, the coating treatment apparatus comprising:
a holding and rotating part configured to hold and rotate the substrate;
a coating solution supply nozzle configured to supply the coating solution to the peripheral portion of the substrate held by the holding and rotating part;
a moving mechanism configured to move the coating solution supply nozzle; and
a controller configured to control the holding and rotating part, the coating solution supply nozzle, and the moving mechanism, wherein
the controller is configured to perform control of, while rotating the holding and rotating part which holds the substrate:
moving the coating solution supply nozzle from an outside of a perimeter of the substrate to a predetermined position at a periphery on the substrate at a first speed by controlling the moving mechanism while supplying the coating solution by the coating solution supply nozzle; and
then moving the coating solution supply nozzle from the predetermined position to the outside of the perimeter of the substrate at a second speed higher than the first speed by controlling the moving mechanism while supplying the coating solution by the coating solution supply nozzle.

2. The coating treatment apparatus according to claim 1, wherein
the second speed is a speed exceeding 50 mm/sec.

3. The coating treatment apparatus according to claim 1, wherein
a rotation speed of the holding and rotating part is 500 rpm or more.

4. The coating treatment apparatus according to claim 1, wherein
the second speed is a speed exceeding 50 mm/sec, and a rotation speed of the holding and rotating part is 500 rpm or more.

5. The coating treatment apparatus according to claim 4, wherein
the rotation speed of the holding and rotating part is 800 rpm to 2000 rpm.

6. A coating treatment method for applying a coating solution to a peripheral portion of a substrate, the coating treatment method comprising:
while rotating the substrate, moving a coating solution supply nozzle from an outside of a perimeter of the substrate to a predetermined position at a periphery on the substrate at a first speed while supplying the coating solution by the coating solution supply nozzle; and
then moving the coating solution supply nozzle from the predetermined position to the outside of the perimeter of the substrate at a second speed higher than the first speed while supplying the coating solution by the coating solution supply nozzle.

7. The coating treatment method according to claim 6, wherein
the second speed is a speed exceeding 50 mm/sec.

8. The coating treatment method according to claim 6, wherein
a rotation speed of the substrate is 500 rpm or more.

9. The coating treatment method according to claim 6, wherein
the second speed is a speed exceeding 50 mm/sec, and a rotation speed of the holding and rotating part is 500 rpm or more.

10. The coating treatment method according to claim 9, wherein
the rotation speed of the holding and rotating part is 800 rpm to 2000 rpm.

11. A computer-readable storage medium storing a program running on a computer of a controller for controlling a coating treatment apparatus so as to cause the coating treatment apparatus to execute a coating treatment method for applying a coating solution to a peripheral portion of a substrate,
the coating treatment apparatus comprising: a holding and rotating part configured to hold and rotate the substrate; a coating solution supply nozzle configured to supply the coating solution to the peripheral portion of the substrate held by the holding and rotating part; and a moving mechanism configured to move the coating solution supply nozzle, and
the coating treatment method comprising:
while rotating the substrate, moving the coating solution supply nozzle from an outside of a perimeter of the substrate to a predetermined position at a periphery on the substrate at a first speed while supplying the coating solution by the coating solution supply nozzle; and
then moving the coating solution supply nozzle from the predetermined position to the outside of the perimeter of the substrate at a second speed higher than the first speed while supplying the coating solution by the coating solution supply nozzle.

12. The computer storage medium according to claim 11, wherein
the second speed is a speed exceeding 50 mm/sec.

13. The computer storage medium according to claim 11, wherein
a rotation speed of the substrate is 500 rpm or more.
